(19) United States
(12) Patent Application Publication
(10) Pub. No.: US 2007/0274809 A1
(43) Pub. Date: Nov. 29, 2007

(54) SUBSTRATE CASSETTE AND TRANSPORT SYSTEM THEREOF

(76) Inventors: Hsien-Chang Kao, Taoyuan County (TW); Chih-Chiang Lee, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,922

(22) Filed: May 26, 2006

(51) Int. Cl. H01L 21/677

(52) U.S. Cl. 414/217

(57) ABSTRACT

A substrate cassette suitable for storing at least a substrate is provided. The substrate cassette includes a top plate, a bottom plate, multiple supports and multiple suspending arms. The top plate is opposite to the bottom plate, and the supports are connected to the top plate and the bottom plate to form a storage space. The suspending arms are fixed on the supports, and each suspending arm extends from the support to the inside of the storage space. Wherein, one of the suspending arms is fixed on each support at the same horizontal level for carrying the substrate. The substrate cassette has multiple substrate input and output entrances, and each substrate input and output entrance is located between the adjacent supports. Besides, a transport system is also provided.

### BACKGROUND OF THE INVENTION

1. Field of Invention

The present invention relates to a structure of a cassette. More particularly, the present invention relates to a structure of a substrate cassette.

2. Description of Related Art

With the advancement of the modern video technology, various displays have been widely used in the display screens of consumer electronic products, such as mobile phones, notebooks, digital cameras and personal digital assistants (PDA). Among these displays, the LCD (liquid crystal display) and the OLED (organic light emitting diode) become predominant in the market owing to the advantages including light weight, small volume and low power consumption and the like.

In the preliminary process for fabricating either the LCD or the OLED, pixel units are formed on a substrate by utilizing semiconductor process. The size of the elements defined on the substrate is reduced continuously as the fabrication of elements is developed towards a higher-density design. The relevant circuit design thus becomes more complicated, and thereby during the relevant display process, the desired pixel units can be formed on a substrate only after several steps are conducted. Therefore, a specific batch of substrates is transported back and forth among several processing machines and processed with required steps from the verification period to the delivery of products. In order to prevent the substrates from being damaged or away from dust during the repeated transportation, the operators store the substrate into a substrate cassette and move the substrate cassette to the next operating machine through a transportation arm for a series of processes.

FIG. 1 is a schematic stereogram of a conventional substrate cassette. Referring to FIG. 1, the conventional substrate cassette 100 is a box structure, composed of multiple plates 110, suitable for disposing several substrates 50. The substrate cassette 100 has an opening 120. The opening 120 serves as both for input and output of the substrates 50. When desired, the substrates 50 can be taken out from the substrate cassette 100 via the opening 120 by a transport arm (not shown) and then transported to a specific machine to be processed; otherwise, the substrates 50 are transported to the substrate cassette 100 via the opening 120 and then stored therein.

As described above, since the substrate cassette 100 only has a single opening 120 for inputting and outputting the substrates 50, the substrate cassette 100 should be accurately positioned to make the opening 120 face the transport arm, thereby increasing the difficulty in designing the relative positions of the machines. Furthermore, for the substrate cassette 100 with a single opening 120, only one transport arm can be used at a time to store and withdraw the substrates 50, thereby limiting the speed of storing and withdrawing the substrates 50.

FIG. 2 is a schematic view of a conventional transport system of a substrate cassette. Referring to FIG. 2, the conventional transport system 200 of a substrate cassette comprises a transport arm 210, a first conveyer 220, a second conveyer 230, a checking machine 240 and a substrate cassette 100 as shown in FIG. 1. The first conveyer 220, the second conveyer 230, the checking machine 240 and the substrate cassette 100 are located at four sides of the transport arm 210, respectively. Additionally, the transport arm 210 is surrounded by a safety fence 250 to keep the operators away from accidental injuries when carelessly entering the operating area of the transport arm 210.

As described above, since the first conveyer 220, the second conveyer 230, the checking machine 240 and the substrate cassette 110 are located around the transport arm 210, the space occupied by the transport system 200 of a substrate cassette cannot be reduced, as well as the area surrounded by the safety fence 250.

### SUMMARY OF THE INVENTION

In view of the above, an object of the present invention is to provide a substrate cassette with input and output entrances in different directions.

A further object of the invention is to provide a transport system of a substrate cassette for reducing the disposition area of machines.

In order to achieve the aforementioned and other objects, the invention provides a substrate cassette suitable for storing at least one substrate. The substrate cassette comprises a top plate, a bottom plate, multiple supports and multiple suspending arms. The top plate is opposite to the bottom plate, and the supports are connected to the top plate and the bottom plate to form a storage space. The suspending arms are fixed on the supports, and each suspending arm extends from the support to the inside of the storage space. Wherein, one of the suspending arms is fixed on each support at the same horizontal level for carrying the substrate. Furthermore, the substrate cassette has multiple substrate input and output entrances, and each substrate input and output entrance is located between the adjacent supports.

In one embodiment of the invention, the foregoing substrate input and output entrance includes an output entrance and an output entrance adjacent to the input entrance, so that the direction of inputting the substrates into the substrate cassette is perpendicular to the direction of outputting the substrates from the substrate cassette.

In one embodiment of the invention, the foregoing substrate input and output entrance includes an output entrance and an output entrance opposite to the input entrance, so that the direction of inputting the substrates into the substrate cassette is parallel to the direction of outputting the substrates from the substrate cassette.

In one embodiment of the invention, the substrate cassette further comprises at least one side plate covering the substrate input and output entrance that is not used for the input entrance and the output entrance.

In one embodiment of the invention, the thickness of the foregoing suspending arm closer to the support can be greater than that farther from the support.

In one embodiment of the invention, the thickness of the suspending arm can be reduced gradually from the support to the inside of the storage space.

In one embodiment of the invention, the width of the suspending arm closer to the support is greater than that farther from the support.

In one embodiment of the invention, the width of the foregoing suspending arm is reduced gradually from the support to the inside of the storing space.

In one embodiment of the invention, the foregoing suspending arm has an elevation angle preferably between 0.1° and 5°.

In one embodiment of the invention, the cross section of the foregoing suspending arm can be shaped as one of a column and a plate.

In one embodiment of the invention, the substrate cassette further comprises multiple contact pads disposed on the surface of each suspending arm.

In one embodiment of the invention, the material of the foregoing contact pad may be one of metal and plastic.

In one embodiment of the invention, the material of the foregoing suspending arm may be the same as that of the support.

In one embodiment of the invention, the material of the foregoing suspending arm may be one of metal and plastic.

In one embodiment of the invention, the material of the foregoing support may be one of metal and plastic.

In one embodiment of the invention, the foregoing support and suspending arm may be integrated as a whole.

In one embodiment of the invention, each of the supports and each of the suspending arms are locked together by, for example, one of a screw and a fastening means.

In one embodiment of the invention, the substrate cassette further comprises several positioning blocks on the bottom of the supports.

In one embodiment of the invention, each of the supports is locked to the top plate and the bottom plate by, for example, one of a screw and a fastening means.

In order to achieve the aforementioned and other objects, the invention further proposes a transport system of a substrate cassette, comprising a transport arm, a first conveyer, a second conveyer, a checking machine and a substrate cassette as described above. The transport arm has a first side, a second side opposite to the first side and a third side adjacent to both the first and second sides. The first conveyer is disposed at the first side of the transport arm, and the second conveyer is disposed at the second side of the transport arm. The checking machine is disposed at the third side of the transport arm. The substrate cassette is disposed on the second conveyer.

In one embodiment of the invention, the transport system further comprises a fence surrounding the transport arm.

In view of the above, since the substrate cassette of the invention has input entrances and output entrances in different directions, it is more convenient to store and withdraw the substrates by associating with the transport arm. Besides, the speed of storing and withdrawing substrates can be accelerated when at least two transport arms are disposed at the input entrances and output entrances of the substrate cassette. Furthermore, since the substrate cassette is disposed on the second conveyer in the transport system of the invention, the area occupied by the transport system is smaller, compared to the conventional substrate cassette that is disposed at the side of the transport arm.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a schematic perspective view of a conventional substrate cassette.

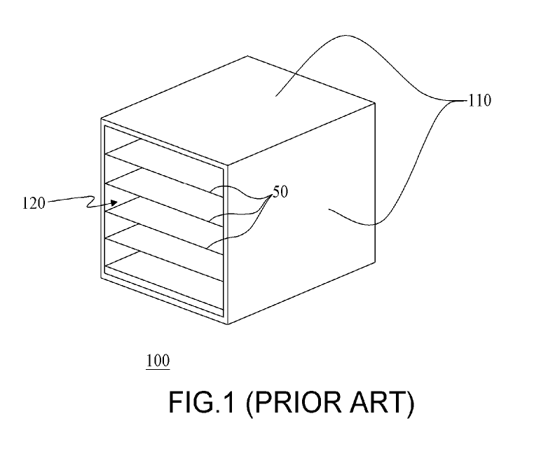

FIG. 2 is a schematic view of a conventional transport system.

FIG. 3A is a schematic perspective view of the substrate cassette according to one embodiment of the invention.

FIG. 3B is a schematic top view of the substrate cassette of FIG. 3A.

FIG. 3C is an enlarged side view of the suspending arms and the supports of FIG. 3B.

FIG. 4A is a schematic perspective view of the substrate cassettes according to another embodiment of the invention.

FIG. 4B is a schematic top view of the substrate cassette of FIG. 4A.

FIG. 5 is a schematic view of the transport system according to one embodiment of the invention.

### DESCRIPTION OF EMBODIMENTS

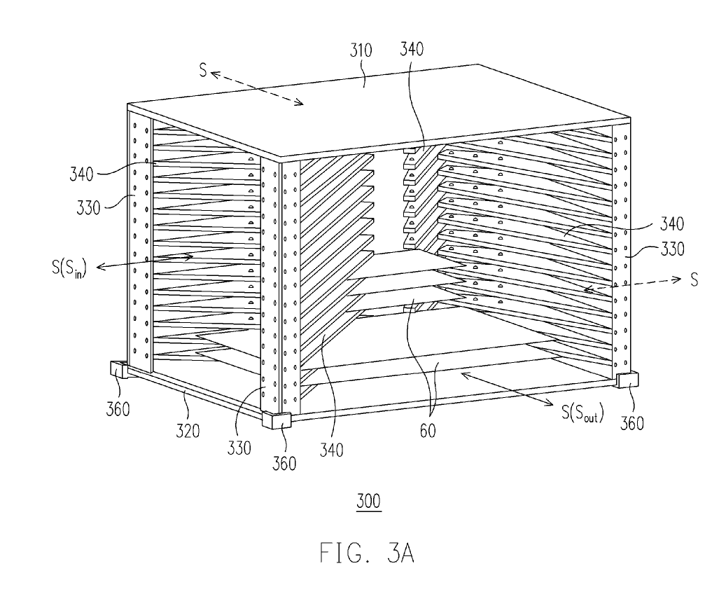

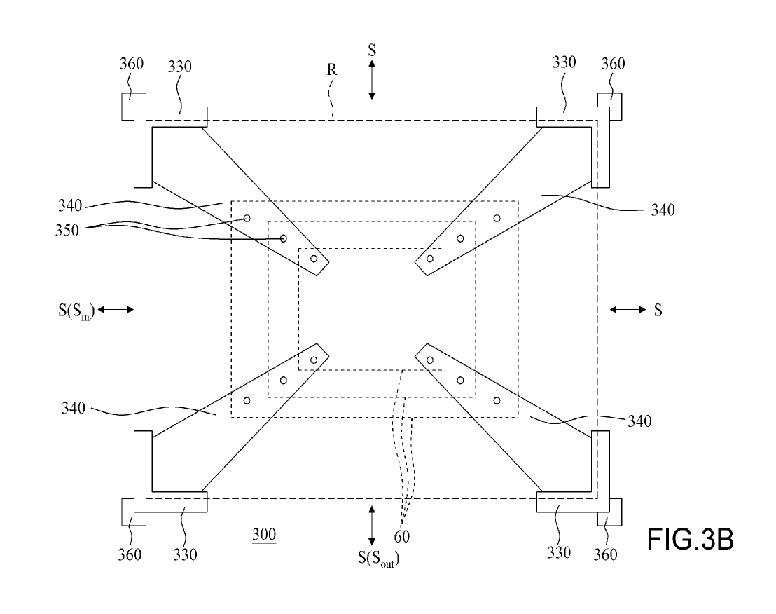

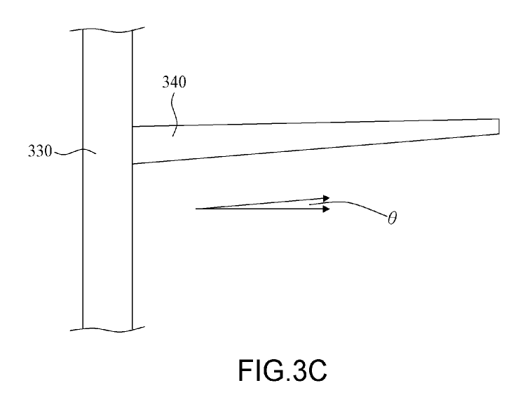

FIG. 3A is a schematic perspective view of the substrate cassette according to one embodiment of the invention, and FIG. 3B is a schematic top view of the substrate cassette of FIG. 3A. Referring to FIGS. 3A and 3B, the substrate cassette 300 of the invention comprises a top plate 310, a bottom plate 320, multiple supports 330 and multiple suspending arms 340. The top plate 310 is opposite to the bottom plate 320. The supports 330 are connected to the top plate 310 and the bottom plate 320 to form a storage space R. The suspending arms 340 are fixed on the corresponding supports 330 and each suspending arm 340 extends from the support 330 to the inside of the storage space R, wherein one of the suspending arms 340 is fixed on each support 330 at the same horizontal level for carrying the substrate 60. Additionally, the substrate cassette 300 has multiple substrate input and output entrances S, and each substrate input and output entrance S is located between the adjacent supports 330.

In the present embodiment, the substrate cassette 300 forms a substantially cuboid storage space R by connecting the top plate 310, the bottom plate 320 and the four supports 330. The storage space R can be divided into many horizontal levels. At the same horizontal level, four suspending arms 340 are used to carry the substrate 60, wherein the substrates 60 may have different sizes. Furthermore, the substrate cassette 300 has four substrate input and output entrances S. It should be noted that the number of the supports 330 is not limited in the invention. For example, the top plate and the bottom plate can be connected by less (or more) than four supports to form a storage space of other shape. As such, the substrate cassette has less (or more) than four substrate input and output entrances.

Referring to FIGS. 3A and 3B again, the substrate input and output entrances S include an input entrance Sᵢₙ and an output entrance Sₒᵤₜ. In the present embodiment, the input entrance Sᵢₙ is adjacent to the output entrance Sₒᵤₜ, so that the direction of inputting the substrate 60 into the substrate cassette 300 is substantially perpendicular to the direction of outputting the substrate 60 from the substrate cassette 300. Of course, the number of the input entrances Sᵢₙ and the output entrances Sₒᵤₜ or the relative positions therebetween are not limited in the invention. For example, the output entrance Sₒᵤₜ can be opposite to the input entrance Sᵢₙ, or the four substrate input and output entrances S include two opposite input entrances Sᵢₙ and two opposite output entrances Sₒᵤₜ. More particularly, any of the substrate input and output entrances S further can serve as both the input entrance Sᵢₙ and the output entrance Sₒᵤₜ. As such, according to the invention, the substrate 60 can be input into or output from the substrate cassette 300 in the four directions without any limitations. Thereby, it is convenient for the substrate cassette 300 to facilitate the arrangement of the transport arm (not shown). By the way, the substrate cassette 300 still brings more convenience than the conventional art even though the substrate 60 is input into or output from the substrate cassette 300 manually.

In the present embodiment, since the input entrance Sᵢₙ and the output entrance Sₒᵤₜ have been positioned, a side plate (s) (not shown) can be disposed at the substrate input and output entrance(s) S beyond the input entrance Sᵢₙ and the output entrance Sₒᵤₜ, so as to prevent dust from falling into the substrate cassette 300 as far as possible. However, the side plate (s) is not intended to limit the convenience of the substrate cassette 300. The side plate (s) can be dismounted accordingly when the substrate input and output entrances S covered by the side plate (s) are required to be used as the input entrance Sᵢₙ or the output entrance Sₒᵤₜ.

Furthermore, each support 330 is locked to the top plate 310 and the bottom plate 320 by, for example, a screw or a fastening means. Similarly, each support 330 and each suspending arm 340 are also locked together by, for example, a screw or a fastening means. The material of the support 330 and the suspending arm 340 is, for example, metal or plastic. Of course, the invention is not limited to the combination manner and constituent material of the aforementioned means. For example, the support 330 and the suspending arm 340 can be integrated as a whole by injection molding.

Referring to FIG. 3B, in order to make the suspending arms 340 carry the substrate 50 more stably, the substrate cassette 300 further comprises, for example, multiple contact pads 350 for contacting the substrate 60 directly. The contact pads 350 can be made of metal or plastic and disposed on the surface of the suspending arms 340 by means of attaching, locking or pressing. Besides, the contact pads 350 can be disposed at the different positions on the suspending arms 340 depending on the size of the substrate 60, so that the force can be applied to the substrates of different sizes uniformly. By the way, in order to install and position the substrate cassette 300 more accurately and reduce the impact due to errors in alignment, the substrate cassette 300 further comprises multiple positioning blocks 360 disposed on the bottom of the supports 330.

FIG. 3C is an enlarged side view of the suspending arms and the supports of FIG. 3B. Referring to FIGS. 3B and 3C, since the portion of the suspending arm 340 far from the support 330 will easily droop due to its own weight (even due to the weight of the substrate 60), the substrate 60 is prone to shifting when it rests on the suspending arm 340. In order to avoid the foregoing case, according to the invention, the width of the suspending arm 340 closer to the support 330 is greater than that farther from the support 330, and the thickness of the suspending arm 340 closer to the support 330 is greater than that farther from the support 330. As such, since the portion of the suspending arm 340 far from the support 330 is lighter, deformation due to the droop will not easily occur. More particularly, the thickness of the suspending arm 340 is reduced gradually from the support 330 to the inside of the storage space R, and the width of the suspending arm 340 is reduced gradually from the support 330 to the inside of the storage space R.

As described above, the suspending arm 340 can be firstly angled by an elevation angle θ according to the invention. The substrate 60 can buffer the drooping suspending arm 340 when resting on the suspending arm 340, so that the suspending arm 340 can carry the substrate 60 horizontally. In the present embodiment, the preferable range of the elevation angle θ is, for example, between 0.1°-0.5°. Furthermore, as described above, the number and the combination manner of the supports are not limited in the invention, which will be further described in another embodiment in conjunction with the drawings below.

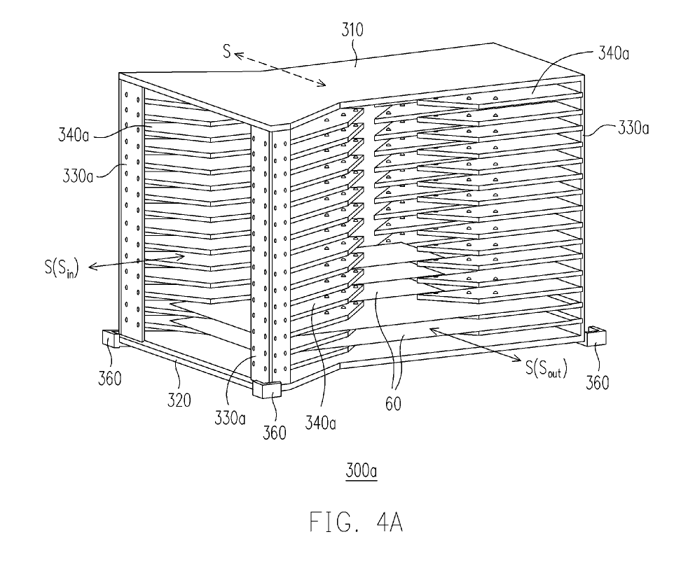

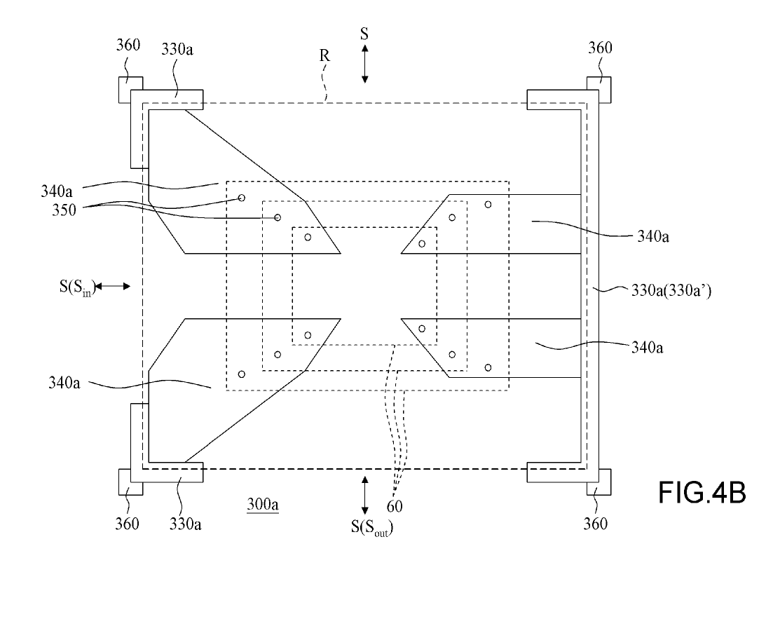

FIG. 4A is a schematic perspective view of the substrate cassette according to another embodiment of the invention, and FIG. 4B is a schematic top view of the substrate cassette of FIG. 4A. Referring to FIGS. 4A and 4B, the substrate cassette 300a of the present embodiment is similar to the substrate cassette 300 (as shown in FIG. 3A) of the foregoing embodiment, and the difference resides in that the substrate cassette 300a of the present embodiment is consisted of three supports 330a. Particularly, as one support 330a′ is shaped as a panel, which not only enhances the strength of the integral structure of the substrate cassette 300a, but also acts as a side plate for preventing dust.

By the way, the shapes of the suspending arms 340a in the present embodiment can be different so as to facilitate the arrangement of the supports 330a and carry the substrate 60 evenly. The manner in which the substrate cassette of the invention is applied to a transport system will be described below in conjunction with the drawings.

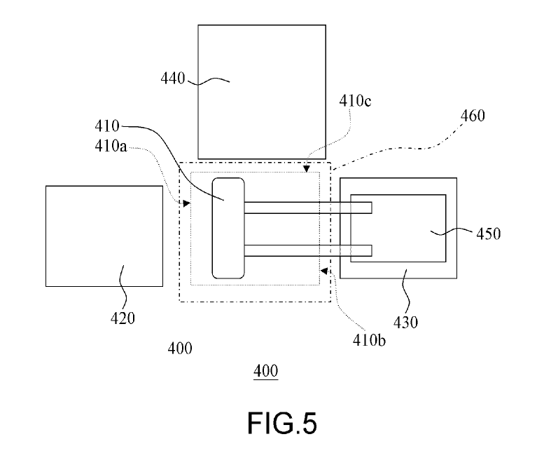

FIG. 5 is a schematic view of the transport system according to one embodiment of the invention. Referring to FIG. 5, the transport system 400 of the invention comprises a transport arm 410, a first conveyer 420, a second conveyer 430, a checking machine 440 and a substrate cassette 450. The substrate cassette 450 can be the aforementioned substrate cassette according to the invention (such as the substrate cassette 300 or 300a). The transport arm 410 has a first side 410a, a second side 410b and a third side 410c. Wherein, the second side 410b is opposite to the first side 410a, and the third side 410c is adjacent to the first side 410a and the second side 410b. The first conveyer 420 is disposed at the first side 410a of the transport arm 410, and the second conveyer 430 is disposed at the second side 410b of the transport arm 410. The checking machine 440 is disposed at the third side 410c of the transport arm 410. Furthermore, the substrate cassette 450 is disposed on the second conveyer 430.

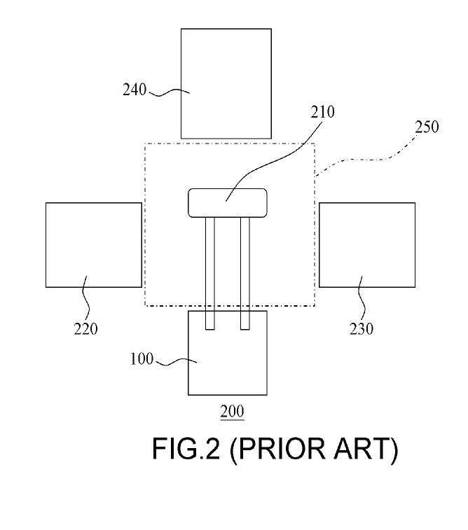

The substrate cassette 450 is not limited to be merely disposed at the side opposite to the third side 410c in the transport arm 410 as it has input and output entrances in different directions. More particularly, the substrate cassette 450 can be disposed on the second conveyer 430 depending on the direction of substrate transport in the overall transport system 400. As such, the transport system 400 occupies smaller area (reduced by 15.5% compared to the transport system 200 shown in FIG. 2), and thereby the machines in a factory can be disposed more flexibly.

It should be noted that the substrate cassette 450 is not limited to be disposed on the second conveyer 430, and it can also be disposed on the first conveyer 420 or the checking machine 440. Furthermore, the number of the substrate cassettes 450 is not limited in the invention and can increase or reduce according to the transport volume of the substrates in the transport system 400. In addition, the checking machine 440 can also be replaced with a processing machine according to the current design plan of the transport system 400.

As described above, a safety fence 460 can be disposed around the transport arm 410 to keep the operators away from for entering the operating area of the transport arm 410 carelessly, which may cause injuries. Since the machines or substrate cassette are not disposed at the side opposite to the third side 410c in the transport arm 410 in the invention, the area surrounded by the safety fence 460 is smaller, and therefore the space utilization of the factory is increased and the cost of the safety fence 460 is reduced.

In view of the above, the substrate cassette and the transport system of the invention at least have the advantages as follows:

1. The substrate cassette has input entrances and output entrances in different directions, so the substrate can be stored and withdrawn conveniently by associating with the transport arms. Particularly, as the input entrance is substantially perpendicular to the output entrance, two transport arms can be disposed at the input entrance and the output entrance accordingly to accelerate the speed of storing and withdrawing substrates.

2. The suspending arm can carry the substrates of different sizes without any modification. Furthermore, the suspending arm has different thickness or width at different positions, so to carry the substrates more evenly.

3. Since the substrate cassette in the transport system is disposed on the second conveyer, the transport system occupies a small area, and the area surrounded by the safety fence is small, and thereby the cost of the safety fence is relatively reduced.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A substrate cassette suitable for disposing at least one substrate, comprising:
a top plate;
a bottom plate opposite to the top plate;
multiple supports connected to the top plate and the bottom plate to form a storage space; and
multiple suspending arms fixed on the supports, and each of the suspending arms extending from the support to the inside of the storage space, wherein one of the suspending arms is fixed on each support at the same horizontal level for carrying the substrate,
wherein the substrate cassette has multiple substrate input and output entrances, each substrate input and output entrance located between the adjacent supports.

2. The substrate cassette as claimed in claim 1, wherein the substrate input and output entrance includes an input entrance and an output entrance adjacent to the input entrance, so that the direction of inputting the substrate into the substrate cassette is perpendicular to the direction of outputting the substrate from the substrate cassette.

3. The substrate cassette as claimed in claim 2, further comprising at least a side plate covering a substrate input and output entrance that is not used as the output entrance and the input entrance.

4. The substrate cassette as claimed in claim 1, wherein the thickness of the suspending arm closer to the support is greater than the thickness of the suspending arm farther from the support.

5. The substrate cassette as claimed in claim 4, wherein the thickness of the suspending arm is reduced gradually from the support to the inside of the storage space.

6. The substrate cassette as claimed in claim 1, wherein the width of the suspending arm closer to the support is greater than the width of the suspending arm farther from the support.

7. The substrate cassette as claimed in claim 6, wherein the width of the suspending arm is reduced gradually from the support to the inside of the storage space.

8. The substrate cassette as claimed in claim 1, wherein each suspending arm has an elevation angle between 0.1° and 5°.

9. The substrate cassette as claimed in claim 1, further comprising multiple contact pads disposed on the surface of each of the suspending arms.

10. The substrate cassette as claimed in claim 9, wherein the material of the contact pad is one of metal and plastic.

11. The substrate cassette as claimed in claim 1, wherein the cross section of the suspending arm is shaped as one of a column and a plate.

12. The substrate cassette as claimed in claim 1, wherein the material of the suspending arm is the same as that of the support.

13. The substrate cassette as claimed in claim 1, wherein the material of the suspending arm is one of metal and plastic.

14. The substrate cassette as claimed in claim 1, wherein the material of the support is one of metal and plastic.

15. The substrate cassette as claimed in claim 1, wherein the support and the suspending arm are integrated as a whole.

16. The substrate cassette as claimed in claim 1, wherein each of the supports and each of the suspending arms are locked together through one of a screw and a fastening means.

17. The substrate cassette as claimed in claim 1, further comprising multiple positioning blocks disposed on the bottom of the support.

18. The substrate cassette as claimed in claim 1, wherein each of the supports is locked to the top plate and the bottom plate through one of a screw and a fastening means.

19. The substrate cassette as claimed in claim 1, wherein the substrate input and output entrance includes an output entrance and an output entrance opposite to the input entrance, so that the direction of inputting the substrates into the substrate cassette is parallel to the direction of outputting the substrates from the substrate cassette.

20. A transport system of a substrate cassette, comprising:
a transport arm having a first side, a second side opposite to the first side and a third side adjacent to the first side and the second side;
a first conveyer disposed at the first side of the transport arm;
a second conveyer disposed at the second side of the transport arm;
a checking machine disposed at the third side of the transport arm; and
a substrate cassette as claimed in claim 1 disposed on the second conveyer.

21. The transport system of a substrate cassette as claimed in claim 20, further comprising a fence disposed around the transport arm.
